(19) United States
(12) Patent Application Publication
(10) Pub. No.: US 2026/0173900 A1
(43) Pub. Date: Jun. 18, 2026

(54) PACKAGE STRUCTURE

(71) Applicant: JCET Semiconductor (Suqian) Co., LTD., Suqian (CN)

(72) Inventors: Kai LIU, Suqian (CN); Sai XU, Suqian (CN)

(21) Appl. No.: 19/414,011

(22) Filed: Dec. 9, 2025

(30) Foreign Application Priority Data
Dec. 13, 2024 (CN) 202411849788.3

(51) Int. Cl. H10W 70/40; H10W 40/20; H10W 40/25; H10W 72/50; H10W 90/00

(52) U.S. Cl. CPC H10W 70/461; H10W 40/235; H10W 40/258; H10W 72/5522; H10W 72/5524; H10W 72/5525; H10W 90/756

(57) ABSTRACT

A package structure, the structure including: a base; a device chip mounted on the base; a molding layer located on the base and covering the device chip; and a first heat dissipation lead exposed from the molding layer and connected with a side portion of the base, the first heat dissipation lead including a first connection portion and a first extension portion in bent connection with it, the first connection portion is connected with the side portion of the base, and the first extension portion and the side wall of the molding layer are arranged opposed to each other.

### CROSS-REFERENCE TO RELATED APPLICATIONS

This application claims the benefit of priority to Chinese Application No. 202411849788.3, filed Dec. 13, 2024, which is incorporated herein by reference in its entirety.

### TECHNICAL FIELD

The embodiments of the present disclosure relate to the field of semiconductor package, and particularly relates to a package structure.

### BACKGROUND

Leadframe packages such as DIP (Dual In-line Package), SOT (Small Outline Transistor), QFP (Quad Flat Package), SOP (Small Outline Package), SON (Small Outline No-leads Package), etc., are still widely used in fields such as consumer electronics, automotive and medical, etc., due to their characteristics such as low cost, small size, and high reliability, etc.

### SUMMARY

The embodiments of the present disclosure provide a package structure, which includes: a base; a device chip mounted on the base; a molding layer located on the base and covering the device chip; and a first heat dissipation lead exposed from the molding layer and connected with a side portion of the base, the first heat dissipation lead includes a first connection portion and a first extension portion in bent connection with it, the first connection portion is connected with the side portion of the base, and the first extension portion and the side wall of the molding layer are arranged opposed to each other.

Optionally, the width of the first connection portion is less than the width of the first extension portion.

Optionally, the number of the first connection portions between the first extension portion and the base is one; or, the number of first connection portions between the first extension portion and the base is multiple.

Optionally, when the number of first connection portions between the first extension portion and the base is multiple, the distances between the adjacent first connection portions are equal.

Optionally, the package structure further includes: a second heat dissipation lead exposed from the molding layer and connected with the first extension portion of the first heat dissipation lead, and the second heat dissipation lead includes a second connection portion and a second extension portion in bent connection with it, the second connection portion being connected with the first extension portion, the second extension portion and the top of the molding layer being arranged opposed to each other.

Optionally, the number of second connection portions between the first extension portion and the second extension portion is one or more.

Optionally, the package structure further includes: an adhesive layer located between the side wall of the molding layer and the first heat dissipation lead, and located between the top of the molding layer and the second heat dissipation lead, and the molding layer, the first heat dissipation lead, and the second heat dissipation lead are in contact with the adhesive layer.

Optionally, the package structure further includes: an adhesive layer located between the side wall of the molding layer and the first heat dissipation lead, and the adhesive layer is in contact with the molding layer and the first heat dissipation lead.

Optionally, the material of the adhesive layer includes one of epoxy resin or thermal conductive adhesive.

Optionally, the top of the first extension portion is flush with the top of the molding layer.

Optionally, the package structure further includes: a heat dissipation cover fixed at the outer side wall of the first heat dissipation lead, and the molding layer is arranged within a cavity enclosed by the heat dissipation cover and the base.

Optionally, the heat dissipation cover includes a heat dissipation top cover and a heat dissipation side cover connected with the edge of the heat dissipation top cover, and the heat dissipation side cover abuts against the first extension portion.

Optionally, the outer side wall of the first extension portion has a protruding portion; the heat dissipation cover includes a heat dissipation top cover and a heat dissipation side cover connected with the edge of the heat dissipation top cover, and the inner wall of the heat dissipation cover has a locking groove, and the protruding portion is embedded into the locking groove.

Optionally, the material of the heat dissipation cover includes one or more of copper, aluminum, ceramic, and graphene.

Optionally, the first heat dissipation lead is connected with two sides of the base in a first direction; and the package structure further includes: functional leads arranged on two sides of the base in a second direction, the functional leads being spaced apart from the base, and the first direction being perpendicular to the second direction.

Optionally, the package structure further includes: lead wires arranged above the base, one end of the lead wires being electrically connected with the chip, and another end of the lead wires being electrically connected with the functional leads; and the molding layer further covers the lead wires and the electrical connection positions of the lead wires with the functional leads.

Optionally, the material of the lead wires includes one or more of copper, gold, silver, nickel, palladium, and aluminum.

### BRIEF DESCRIPTION OF THE DRAWINGS

FIGS. 1 to 4 are corresponding structural schematic diagrams in the first embodiment of the package structure of the present disclosure;

FIGS. 5 to 6 are corresponding structural schematic diagrams in the second embodiment of the package structure of the present disclosure;

FIG. 7 is a corresponding structural schematic diagram in the third embodiment of the package structure of the present disclosure;

FIG. 8 is a corresponding structural schematic diagram in the fourth embodiment of the package structure of the present disclosure; and

FIGS. 9 to 10 are corresponding structural schematic diagrams in the fifth embodiment of the package structure of the present disclosure.

### DETAILED DESCRIPTION

With the enhancement of chip functions and the increase of power consumption, the heat generated by the chip in work process also increases. Currently, package structures can no longer meet the requirements of high heat dissipation performance.

The problem to be solved by the embodiments of the present disclosure is to provide a package structure, which improves the heat dissipation performance of the package structure and reduces the horizontal dimensions of the package structure.

In order to solve the above technical problem, the embodiments of the present disclosure provide a package structure, which includes: a base; a device chip mounted on the base; a molding layer located on the base and covering the device chip; and a first heat dissipation lead exposed from the molding layer and connected with the side portion of the base, the first heat dissipation lead including a first connection portion and a first extension portion in bent connection with it, the first connection portion is connected with the side portion of the base, and the first extension portion and the side wall of the molding layer are arranged opposed to each other.

Compared with the prior art, the technical solutions of the embodiments of the present disclosure have the following advantages. In the package structure provided by the embodiments of the present disclosure, the device chip is mounted on the base, the molding layer is located on the base and covers the device chip, and the first heat dissipation lead is exposed from the molding layer and is connected with the side portion of the base, and the first heat dissipation lead includes a first connection portion and a first extension portion in bent connection with it, and the first connection portion is connected with the side portion of the base, and the first extension portion and the side wall of the molding layer are arranged opposed to each other. In the embodiments of the present disclosure, by arranging the first heat dissipation lead exposed from the molding layer and connected with the side portion of the base, the first heat dissipation lead is brought into direct contact with the air environment, thereby enabling heat generated by the chip in working state to be dissipated rapidly through the first heat dissipation lead, which improves the heat dissipation performance of the package structure, meanwhile, the first heat dissipation lead includes a first connection portion and a first extension portion in bent connection with it, so that the first connection portion and the first extension portion are in a bent state, which reduces the horizontal dimensions of the package structure; in summary, by arranging the first heat dissipation lead exposed from the molding layer and connected with the side portion of the base, not only the heat dissipation performance of the package structure can be improved, but also the horizontal dimensions of the package structure can be reduced, thereby improving the product competitiveness of the package structure.

In order to make the above objects, characteristics, and advantages of the embodiments of the present disclosure more obvious and understandable, the specific embodiments of the present disclosure are described in detail below in conjunction with the accompanying drawings.

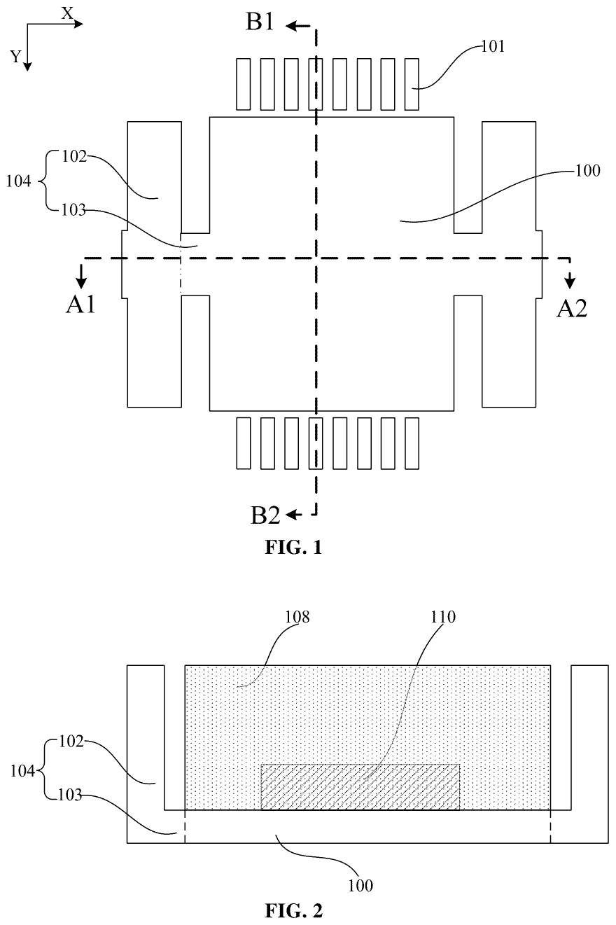

FIGS. 1 to 4 are corresponding structural schematic diagrams in the first embodiment of the package structure of the present disclosure. Wherein FIG. 1 is a top view schematic diagram of the package structure, FIG. 2 is a cross-sectional schematic diagram of FIG. 1 along the A1A2 direction; FIG. 3 is a cross-sectional schematic diagram of FIG. 1 along the A1A2 direction.

The package structure includes: a base 100; a device chip 110 mounted on the base 100; a molding layer 108 located on the base 100 and covering the device chip 110; and a first heat dissipation lead 104 exposed from the molding layer 108 and connected with the side portion of the base 100, the first heat dissipation lead 104 including a first connection portion 103 and a first extension portion 102 in bent connection with it, the first connection portion 103 is connected with the side portion of the base 100, and the first extension portion 102 and the side wall of the molding layer 108 are arranged opposed to each other.

It should be noted that by arranging the first heat dissipation lead 104 exposed from the molding layer 108 and connected with the side portion of the base 100, the first heat dissipation lead 104 is brought into direct contact with the air environment, thereby enabling heat generated by the chip in working state to be dissipated rapidly through the first heat dissipation lead 104, which improves the heat dissipation performance of the package structure, meanwhile, the first heat dissipation lead 104 includes a first connection portion 103 and a first extension portion 102 in bent connection with it, so that the first connection portion 103 and the first extension portion 102 are in a bent state, which reduces the horizontal dimensions of the package structure; in summary, by arranging the first heat dissipation lead 104 exposed from the molding layer 108 and connected with the side portion of the base 100, not only the heat dissipation performance of the package structure can be improved, but also the horizontal dimensions of the package structure can be reduced, thereby improving the product competitiveness of the package structure.

Specifically, the base 100 provides a carrier platform for arranging the device chip 110 to support the device chip 110.

As an example, the base 100 is a metal base. In the present embodiment, the material of the base 100 includes copper or iron-nickel alloy.

Specifically, copper or iron-nickel alloys exhibit excellent electrical conductivity, high thermal conductivity, and have low coefficient of thermal expansion, meanwhile, they further have good corrosion resistance and oxidation resistance.

It should be noted that the device chip 110 is a chip with a specific function.

Specifically, the type of device chip 110 is determined according to actual functional requirements or application scenarios, for example, device chip 110 includes one or more of a System-on-Chip (SoC), a memory chip, an Application-Specific Integrated Circuit (ASIC) chip, a Central Processing Unit (CPU) chip, a Graphics Processing Unit (GPU) chip, and an Field-Programmable Gate Array (FPGA) chip.

Specifically, the molding layer 108 serves to protect the device chip 110, prevent the device chips 110 from cross-talking with each other, and it reduces the probability of damage to the device chip 110 and contamination from the air environment, meanwhile, the device chip 110 and base molded by the molding layer 108 are further conducive for installation and transportation.

In the present embodiment, the material of the molding layer 108 includes a molding material. Specifically, the material of the molding material includes epoxy resin, the epoxy resin has the advantages such as low shrinkage rate, good adhesion, excellent corrosion resistance, superior electrical properties, and relatively low cost, etc.

It should be noted that the material of the molding material may further include one or more of a hardener, a catalyst, or a filler.

It should also be noted that the molding layer 108 needs to be cured and baked to make the molecular chain cross reaction in the molding layer 108 more thorough, so as to have more stable physical and chemical properties, and release the internal stress in the molding layer 108.

Specifically, by arranging the first heat dissipation lead 104 exposed from the molding layer 108 and connected with the side portion of the base 100, the first heat dissipation lead 104 is brought into direct contact with the air environment, thereby enabling heat generated by the chip in working state to be dissipated rapidly through the first heat dissipation lead 104, which improves the heat dissipation performance of the package structure, meanwhile, the first heat dissipation lead 104 includes a first connection portion 103 and a first extension portion 102 in bent connection with it, so that the first connection portion 103 and the first extension portion 102 are in a bent state, which reduces the horizontal dimensions of the package structure.

It should be noted that the first connection portion 103 is connected with the side portion of the base 100, and the first extension portion 102 is connected with the first connection portion 103, and the heat generated when the device chip 110 is in working state is dissipated through the base 100 and the first connection portion 103 to the first extension portion 102, and since the first extension portion 102 is exposed in the air environment, the heat generated can be rapidly dissipated through the first extension portion 102, thereby improving the heat dissipation performance of the package structure.

As an example, the first heat dissipation lead 104 is connected with two sides of the base 100 in a first direction (as shown in the X-direction in FIG. 1).

Specifically, the first heat dissipation lead 104 is connected with two sides of the base 100 in the first direction, so that the heat generated when the device chip 110 is in working state can be evenly dissipated through the first heat dissipation lead 104 on two sides of the base 100, thereby making the heat in various areas of the base 100 uniform and reducing the probability that some regions have high heat and some regions have low heat in the base 100.

It should be noted that by arranging the first connection portion 103 and bending using the first connection portion 103, the first extension portion 102 connected with the first connection portion 103 can be arranged opposed to the side wall of the molding layer 108, which reduces the horizontal dimensions of the package structure, meanwhile, the first connection portion 103 is connected with the first extension portion 102, and the first connection portion 103 provides a heat dissipation channel, so that the heat on the base 100 can enter the first extension portion 102 through the heat dissipation channel provided by the first connection portion 103, which enables the first extension portion 102 to rapidly dissipate the heat.

In the present embodiment, the width of the first connection portion 103 is less than the width of the first extension portion 102.

Specifically, the width of the first connection portion 103 is less than the width of the first extension portion 102, and during the bending process of the first connection portion 103, the difficulty of bending the first connection portion 103 can be reduced, and the first extension portion 102 and the side portion of the molding layer 108 are arranged opposed to each other.

As an example, the number of first connection portions 103 between the first extension portion 102 and the base 100 is one.

In other embodiments, as shown in FIG. 4, the number of first connection portions 103 between the first extension portion 102 and the base 100 is multiple.

Specifically, the number of first connection portions 103 between the first extension portion 102 and the base 100 is multiple, which means that there are a plurality of heat dissipation channels between the first extension portion 102 and the base 100, so that the heat of the base 100 can be rapidly dissipated through a plurality of heat dissipation channels.

As an example, when the number of first connection portions 103 between the first extension portion 102 and the base 100 is multiple, the distances between the adjacent first connection portions 103 are equal.

It should be noted that the distances between the adjacent first connection portions 103 are equal, which can improve the thermal conduction uniformity of a plurality of heat dissipation channels, thereby making the heat in various areas of the base 100 uniform and reducing the probability that some regions have high heat and some regions have low heat in the base 100.

In the present embodiment, the top of the first extension portion 102 is flush with the top of the molding layer 108.

Specifically, the top of the first extension portion 102 is flush with the top of the molding layer 108, which can improve the flatness of the top surface of the package structure, meanwhile, the top of the first extension portion 102 is flush with the top of the molding layer 108, which can maximize the size of the first extension portion 102 in the normal direction of the base 100, thereby maximizing the heat dissipation area of the package structure, thus effectively improving the heat dissipation performance of the package structure.

In the present embodiment, the package structure further includes: functional leads 101 arranged on two sides of the base 100 in a second direction (as shown in the Y-direction in FIG. 1), the functional leads 101 are spaced apart from the base 100, and the first direction is perpendicular to the second direction.

It should be noted that functional leads 101 are used for electrical connection with the external circuit carrier board and device chip 110, so that the device chip 110 can achieve electrical signal transmission with other electronic components on the external circuit carrier board through the functional leads 101.

It should also be noted that functional leads 101 are arranged on two sides of the base 100 in a second direction, so that the functional leads 101 on one side of the base 100 can serve as a signal input terminal and the functional leads 101 on another side of the base 100 can serve as a signal output terminal, meanwhile, the arrangement directions of the functional leads 101 and the first heat dissipation lead 104 are not consistent, which facilitates the electrical connection between the device chip 110 and the functional leads 101 through lead wires 126, which reduces the risk of mutual interference between the functional leads 101 and the first heat dissipation lead 104, and improves the reliability of the package structure.

In the present embodiment, the package structure further includes: lead wires 126 located above the base 100, one end of the lead wires 126 is electrically connected with the chip and another end of the lead wires 126 is electrically connected with the functional leads 101.

It should be noted that one end of the lead wires 126 is electrically connected with the chip, and another end of the lead wires 126 is electrically connected with the functional leads 101, the lead wires 126 serve to achieve an electrical connection of the device chip 110 with the functional leads 101, so that the device chip 110 can be electrically connected with other external electronic components through the functional leads 101.

In the present embodiment, the material of the lead wires 126 includes one or more of copper, gold, silver, nickel, palladium, and aluminum.

Copper, gold, silver, nickel, palladium, and aluminum are all conductive materials commonly used for lead wires 126 in package structures, and the resistivity of copper, gold, silver, nickel, palladium, and aluminum is low, which can improve the electrical conductivity of lead wires 126.

In the present embodiment, the molding layer 108 also covers the lead wires 126 and the electrical connection positions between the lead wires 126 and the functional leads 101.

It should be noted that the molding layer 108 covers the lead wires 126 and the electrical connection positions between the lead wires 126 and the functional leads 101, which can reduce the probability of contamination from the air environment at the lead wires 126 and the electrical connection positions between the lead wires 126 and the functional leads 101, which reduces the probability of electrical failure at the electrical connection positions between the lead wires 126 and the functional leads 101, thus improving the reliability of the package structure.

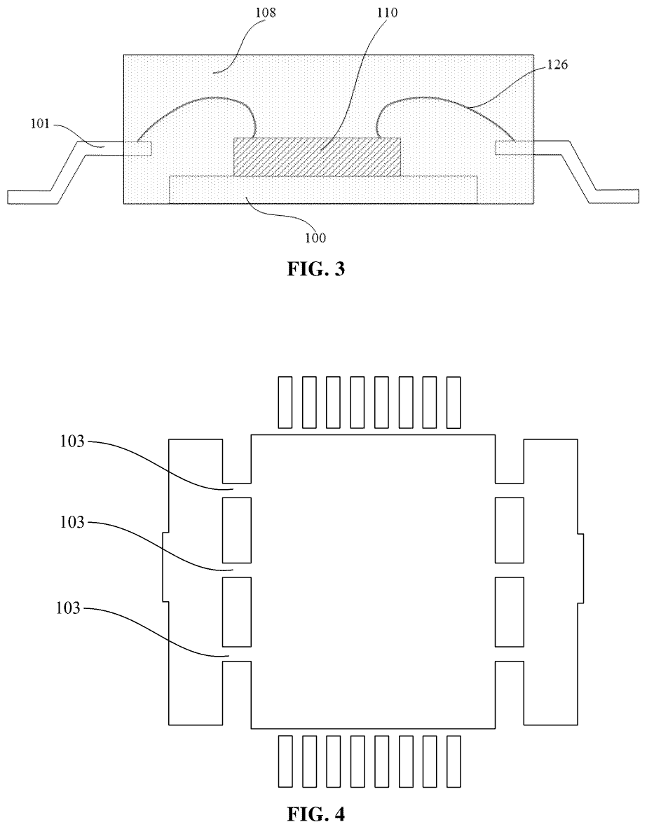

FIGS. 5 to 6 are corresponding structural schematic diagrams in the second embodiment of the package structure of the present disclosure. Wherein FIG. 5 is a top view schematic diagram of the package structure, and FIG. 6 is a cross-sectional schematic diagram of FIG. 5 along the A1A2 direction.

The similarities between the package structure of the present disclosure and the first embodiment will not be repeated herein, and the differences between the package structure of the present disclosure and the first embodiment lie in:
Referring to FIGS. 5 to 6, the package structure further includes: a second heat dissipation lead 263 exposed from the molding layer 208 and connected with the first extension portion 202 of the first heat dissipation lead 204, and the second heat dissipation lead 263 includes a second connection portion 261 and a second extension portion 262 in bent connection with it, and the second connection portion 261 is connected with the first extension portion 202, and the second extension portion 262 and the top of the molding layer 208 are arranged opposed to each other.

Specifically, the second heat dissipation lead 263 includes a second connection portion 261 and a second extension portion 262 in bent connection with it, and the second heat dissipation lead 263 is exposed from the molding layer 208 and connected with the first extension portion 202 of the first heat dissipation lead 204, which means that the heat dissipation lead composed of the second heat dissipation lead 263 and the first heat dissipation lead 204 is bent twice, and the first extension portion 202 and the side wall of the molding layer 208 are arranged opposed to each other, and the second extension portion 262 and the top of the molding layer 208 are arranged opposed to each other, and when the device chip is in working state, the heat of the base 200 can be rapidly dissipated through the first heat dissipation lead 204 and the second heat dissipation lead 263, the second heat dissipation lead 263 further increases the heat dissipation channel area of the package structure, thereby further improving the heat dissipation performance of the package structure.

It should be noted that by arranging the second connection portion 261 and bending using the second connection portion 261, the second extension portion 262 connected with the second connection portion 261 can be arranged opposed to the top of the molding layer 208, which further increases the heat dissipation channel area of the package structure, and improves the heat dissipation performance of the package structure, meanwhile, the second connection portion 261 is connected with the first extension portion 202, and the second connection portion 261 provides a heat dissipation channel, so that the heat on the first extension portion 202 can enter the second extension portion 262 through the heat dissipation channel provided by the second connection portion 261, so that the second extension portion 262 can rapidly dissipate the heat.

As an example, the number of second connection portions 261 between the first extension portion 202 and the second extension portion 262 is one or more.

Specifically, the number of first connection portions 203 between the first extension portion 202 and the base 200 is one or more, which means that there are one or more heat dissipation channels between the first extension portion 202 and the base 200, so that the heat of the base 200 can be rapidly dissipated through one or more heat dissipation channels.

As an example, as shown in FIG. 5, the number of second connection portions 261 between the first extension portion 202 and the second extension portion 262 is shown as one.

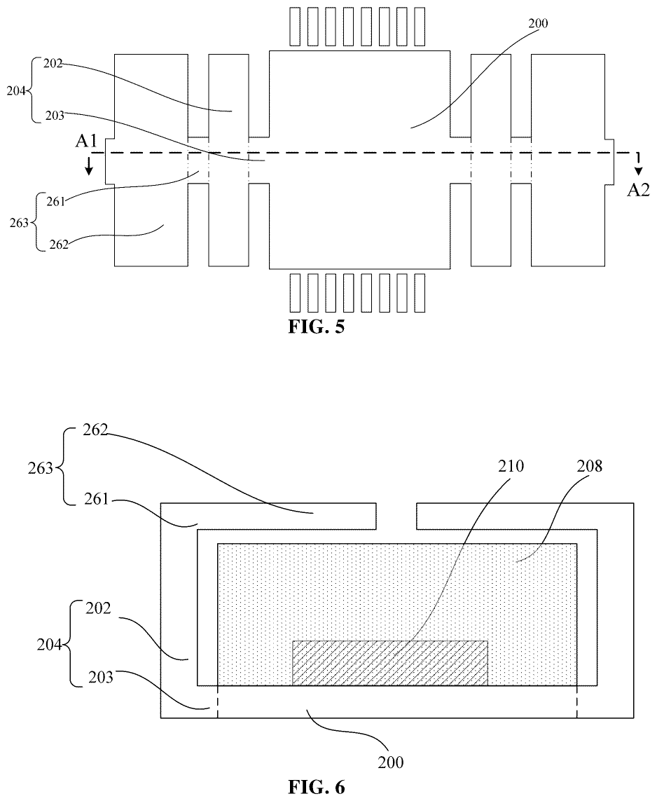

FIG. 7 is a corresponding structural schematic diagram in the third embodiment of the package structure of the present disclosure.

The similarities between the package structure of the present disclosure and the first embodiment will not be repeated herein, and the differences between the package structure of the present disclosure and the first embodiment lie in:
Referring to FIG. 7, the package structure further includes: an adhesive layer 380 located between the side wall of the molding layer 308 and the first heat dissipation lead 304, and the adhesive layer 380 is in contact with the molding layer 308 and the first heat dissipation lead 304.

It should be noted that by arranging the adhesive layer 380 between the side wall of the molding layer 308 and the first heat dissipation lead 304, the stability of the first heat dissipation lead 304 can be improved, which reduces the risk of shaking of the first heat dissipation lead 304 and further improves the reliability of the package structure.

As an example, the material of the adhesive layer 380 includes one of epoxy resin or thermal conductive adhesive.

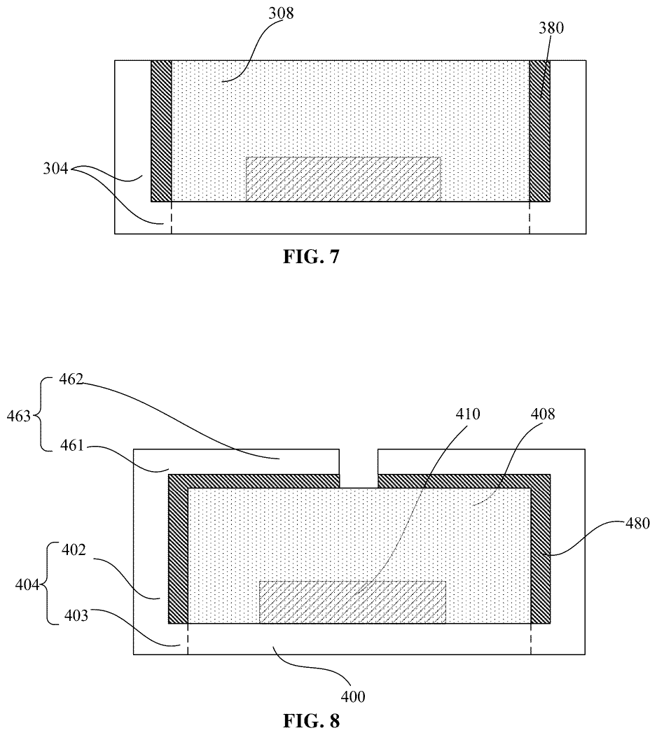

FIG. 8 is a corresponding structural schematic diagram in the fourth embodiment of the package structure of the present disclosure.

The similarities between the package structure of the present disclosure and the first embodiment will not be repeated herein, and the differences between the package structure of the present disclosure and the first embodiment lie in:
Referring to FIG. 8, the package structure further includes: a second heat dissipation lead 463 exposed from the molding layer 408 and connected with the first extension portion 402 of the first heat dissipation lead 404, and the second heat dissipation lead 463 includes a second connection portion 461 and a second extension portion 462 in bent connection with it, and the second connection portion 461 is connected with the first extension portion 402, and the second extension portion 462 and the top of the molding layer 408 are arranged opposed to each other.

Specifically, the second heat dissipation lead 463 includes a second connection portion 461 and a second extension portion 462 in bent connection with it, and the second heat dissipation lead 463 is exposed from the molding layer 408 and connected with the first extension portion 402 of the first heat dissipation lead 404, which means that the heat dissipation lead composed of the second heat dissipation lead 463 and the first heat dissipation lead 404 is bent twice, and the first extension portion 402 and the side wall of the molding layer 408 are arranged opposed to each other, and the second extension portion 462 and the top of the molding layer 408 are arranged opposed to each other, and when the device chip is in working state, the heat of the base 400 can be rapidly dissipated through the first heat dissipation lead 404 and the second heat dissipation lead 463, the second heat dissipation lead 463 further improves the heat dissipation channel area of the package structure, thereby further improving the heat dissipation performance of the package structure.

It should be noted that by arranging the second connection portion 461 and bending using the second connection portion 461, the second extension portion 462 connected with the second connection portion 461 can be arranged opposed to the top of the molding layer 408, which further improves the heat dissipation channel area of the package structure, and improves the heat dissipation performance of the package structure, meanwhile, the second connection portion 461 is connected with the first extension portion 402, and the second connection portion 461 provides a heat dissipation channel, so that the heat on the first extension portion 402 can enter the second extension portion 462 through the heat dissipation channel provided by the second connection portion 461, so that the second extension portion 462 can rapidly dissipate the heat.

As an example, the number of second connection portions 461 between the first extension portion 402 and the second extension portion 462 is one or more.

Specifically, the number of first connection portions 403 between the first extension portion 402 and the base 400 is one or more, which means that there are one or more heat dissipation channels between the first extension portion 402 and the base 400, so that the heat of the base 400 can be rapidly dissipated through one or more heat dissipation channels.

As an example, the package structure further includes: an adhesive layer 480 located between the side wall of the molding layer 408 and the first heat dissipation lead 404, and located between the top of the molding layer 408 and the second heat dissipation lead 463, and the molding layer 408, the first heat dissipation lead 404, and the second heat dissipation lead 463 are in contact with the adhesive layer 480.

It should be noted that by arranging the adhesive layer 480 between the side wall of the molding layer 408 and the first heat dissipation lead 404, as well as between the top of the molding layer 408 and the second heat dissipation lead 463, the stability of the first heat dissipation lead 404 and the second heat dissipation lead 463 can be improved, which reduces the risk of shaking of the first heat dissipation lead 404 and the second heat dissipation lead 463 and further improves the reliability of the package structure.

As an example, the material of the adhesive layer 480 includes one of epoxy resin or thermal conductive adhesive.

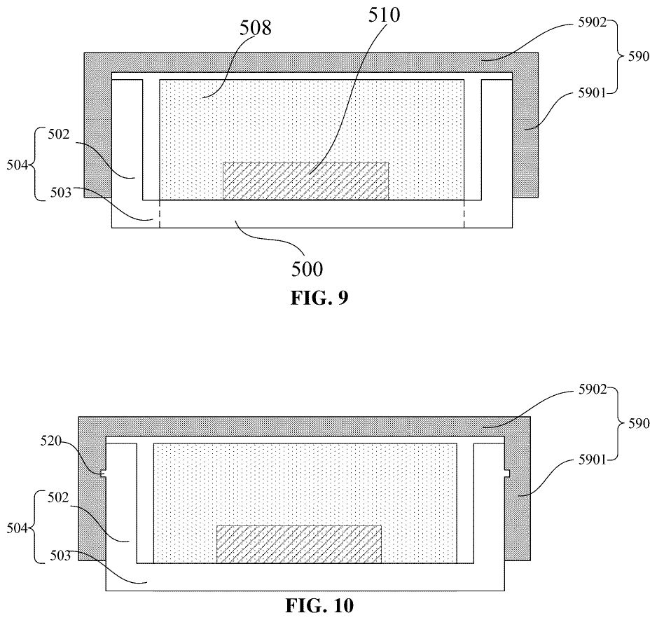

FIGS. 9 to 10 are corresponding structural schematic diagrams in the fifth embodiment of the package structure of the present disclosure. The similarities between the package structure of the present disclosure and the first embodiment will not be repeated herein, and the differences between the package structure of the present disclosure and the first embodiment lie in:

Referring to FIG. 9, the package structure further includes: a heat dissipation cover 590 fixed at the outer side wall of the first heat dissipation lead 504, and the molding layer 508 is located within the cavity enclosed by the heat dissipation cover 590 and the base 500.

It should be noted that by fixing the heat dissipation cover 590 at the outer wall of the first heat dissipation lead 504, the heat in the first heat dissipation lead 504 can enter the heat dissipation cover 590, so that the heat dissipation cover 590 can also serve for heat dissipation, thereby further improving the heat dissipation performance of the package structure.

It should also be noted that the molding layer 508 is located within the cavity enclosed by the heat dissipation cover 590 and the base 500, so that the heat dissipation cover 590 can protect the molding layer 508 and the device chip 510 within the cavity.

In the present embodiment, the heat dissipation cover 590 includes a heat dissipation top cover 5902 and a heat dissipation side cover 5901 connected with the edge of the heat dissipation top cover 5902, and the heat dissipation side cover 5901 abuts against the first extension portion 502.

It should be noted that by arranging the first connection portion 503 and bending using the first connection portion 503, the first extension portion 502 connected with the first connection portion 503 can be arranged opposed to the side wall of the molding layer 508, which means that the first extension portion 502 has elasticity in the outward direction, and when the heat dissipation side cover 5901 abuts against the first extension portion 502, the first extension portion 502 will apply a certain elastic force to the inner wall of the heat dissipation side cover 5901, so that the heat dissipation cover 590 can be fixed on the first heat dissipation lead 504 using the elasticity of the first extension portion 502.

As shown in FIG. 10, in other embodiments, the outer wall of the first extension portion 502 includes a protruding portion 520.

Specifically, when fixing the heat dissipation cover 590 on the outer side wall of the first extension portion 502, the protruding portion 520 serves for fixing and supporting the heat dissipation cover 590, which prevents the risk of the heat dissipation side cover 5901 sliding on the outer wall of the first extension portion 502 and improves the reliability of the package structure.

As an example, the heat dissipation cover 590 includes a heat dissipation top cover 5902 and a heat dissipation side cover 5901 connected with the edge of the heat dissipation top cover 5902, and the inner wall of the heat dissipation cover 590 has a locking groove (not labeled), and the protruding portion 520 is embedded into the locking groove.

Specifically, the locking groove provides a spatial position for placing the protruding portion 520 on the first extension portion 502, so that the protruding portion 520 can be embedded into the locking groove, which improves the stability between the heat dissipation cover 590 and the first heat dissipation lead 504.

In the present embodiment, the material of the heat dissipation cover 590 includes one or more of copper, aluminum, ceramic, and graphene.

Although the present disclosure is disclosed as above, the present disclosure is not limited thereto. Any skilled in the art may also make various changes and modifications without departing from the spirit and scope of the present disclosure, therefore the scope of protection of the present disclosure shall be subject to the scope defined by the claims.

What is claimed is:

1. A package structure, comprising:
a base;
a device chip mounted on the base;
a molding layer located on the base and covering the device chip; and
a first heat dissipation lead exposed from the molding layer and connected with a side portion of the base,
wherein the first heat dissipation lead comprises a first connection portion and a first extension portion in bent connection with it, the first connection portion is connected with the side portion of the base, and the first extension portion and a side wall of the molding layer are arranged opposed to each other.

2. The package structure according to claim 1, wherein a width of the first connection portion is less than a width of the first extension portion.

3. The package structure according to claim 1, wherein a number of the first connection portions between the first extension portion and the base is one.

4. The package structure according to claim 1, wherein a number of first connection portions between the first extension portion and the base is multiple.

5. The package structure according to claim 3, wherein when the number of first connection portions between the first extension portion and the base is multiple, distances between the adjacent first connection portions are equal.

6. The package structure according to claim 1, further comprising a second heat dissipation lead exposed from the molding layer and connected with the first extension portion of the first heat dissipation lead,
wherein the second heat dissipation lead comprises a second connection portion and a second extension portion in bent connection with it, the second connection portion is connected with the first extension portion, the second extension portion and a top of the molding layer are arranged opposed to each other.

7. The package structure according to claim 6, wherein a number of second connection portions between the first extension portion and the second extension portion is one or more.

8. The package structure according to claim 6, further comprising an adhesive layer located between the side wall of the molding layer and the first heat dissipation lead, and located between the top of the molding layer and the second heat dissipation lead,
wherein the molding layer, the first heat dissipation lead, and the second heat dissipation lead are in contact with the adhesive layer.

9. The package structure according to claim 1, further comprising an adhesive layer located between the side wall of the molding layer and the first heat dissipation lead,
wherein the adhesive layer is in contact with the molding layer and the first heat dissipation lead.

10. The package structure according to claim 8, wherein a material of the adhesive layer comprises one of epoxy resin or thermal conductive adhesive.

11. The package structure according to claim 1, wherein a top of the first extension portion is flush with a top of the molding layer.

12. The package structure according to claim 1, further comprising a heat dissipation cover fixed at an outer side wall of the first heat dissipation lead,
wherein the molding layer is arranged within a cavity enclosed by the heat dissipation cover and the base.

13. The package structure according to claim 12, wherein
the heat dissipation cover comprises a heat dissipation top cover and a heat dissipation side cover connected with an edge of the heat dissipation top cover; and
the heat dissipation side cover abuts against the first extension portion.

14. The package structure according to claim 12, wherein
an outer side wall of the first extension portion has a protruding portion; and
the heat dissipation cover comprises a heat dissipation top cover and a heat dissipation side cover connected with an edge of the heat dissipation top cover, and an inner wall of the heat dissipation cover has a locking groove, and the protruding portion is embedded into the locking groove.

15. The package structure according to claim 12, wherein a material of the heat dissipation cover comprises one or more of copper, aluminum, ceramic, and graphene.

16. The package structure according to claim 1, wherein
the first heat dissipation lead is connected with two sides of the base in a first direction; and
the package structure further comprises functional leads arranged on the two sides of the base in a second direction, the functional leads are spaced apart from the base, and the first direction is perpendicular to the second direction.

17. The package structure according to claim 16, further comprising lead wires arranged above the base, one end of the lead wires is electrically connected with the device chip, and another end of the lead wires is electrically connected with the functional leads,
wherein the molding layer also covers the lead wires and electrical connection positions of the lead wires with the functional leads.

18. The package structure according to claim 17, wherein a material of the lead wires comprises one or more of copper, gold, silver, nickel, palladium, and aluminum.
